(19) United States
(12) Patent Application Publication
(10) Pub. No.: US 2003/0057437 A1
(43) Pub. Date: Mar. 27, 2003

(54) Compound semiconductor epitaxial wafer and devices using the same

(76) Inventors: Tatsushi Hashimoto, Ibaraki (JP); Mineo Washima, Ibaraki (JP); Takeshi Tanaka, Ibaraki (JP)

Correspondence Address: FOLEY AND LARDNER, SUITE 500, 3000 K STREET NW, WASHINGTON, DC, 20007, US

(21) Appl. No.: 09/957,453

(22) Filed: Sep. 21, 2001

(51) Int. Cl. H01L 29/06; H01L 29/12; H01L 29/18; H01L 23/544; H01L 23/58

(52) U.S. Cl. 257/190; 257/11; 257/42; 257/615; 257/631; 257/620; 257/189

(57) ABSTRACT

Selenium (or tellurium or sulfur) is doped as an n-type dopant by homogeneous doping or planar doping in a compound semiconductor epitaxial wafer to form a selenium-doped layer. Thus, an epitaxial wafer having high carrier density can be prepared. The use of this epitaxial wafer can lower parasitic resistance and can provide HEMT having high gm. Further, the lowered resistance can significantly increase the freedom of device design.

### BACKGROUND OF THE INVENTION

1. Field of the Invention

The invention relates to a compound semiconductor epitaxial wafer and devices using the same.

2. Prior Art

FIG. 1 is a diagram showing the structure of a conventional compound semiconductor epitaxial wafer.

This epitaxial wafer is an epitaxial wafer for high electron mobility transistors (HEMTs), comprising a semi-insulating gallium arsenic (GaAs) substrate 7 and, provided on the substrate 7, an epitaxial layer, with an indium content of not less than 30%, formed of indium aluminum arsenic (InAlAs)/indium gallium arsenic (InGaAs).

More specifically, in this epitaxial wafer, in order to reduce a difference in lattice constant from the semi-insulating GaAs substrate 7, a graded buffer layer 6 of InAlAs with the indium content being varied in a graded manner, a channel layer 5 of InGaAs, a spacer layer 4 of InAlAs, a silicon-doped layer 3b of InAlAs which has been doped with silicon by homogeneous doping or planar doping, a Schottky contact layer 2 of InAlAs, and an ohmic contact layer 1 of InGaAs doped with one or a plurality of dopants selected from silicon, selenium, tellurium and the like are provided in that order on the semi-insulating GaAs substrate 7.

In the conventional epitaxial wafer, however, an attempt to dope the InAlAs layer with silicon has caused no satisfactory incorporation of the dopant in the crystal, and, consequently, high carrier density could not have been realized. Further, there is a disadvantage that, in the carrier feed layer in the HEMT structure, unless the carrier density is high, the spacing between the gate electrode and the channel layer is increased resulting in increased resistance.

### SUMMARY OF THE INVENTION

Accordingly, it is an object of the invention to solve the above problem of the prior art and to provide a compound semiconductor epitaxial wafer having high carrier density and devices using the same.

According to the first feature of the invention, a compound semiconductor epitaxial wafer comprises a semi-insulating GaAs substrate and, grown on the semi-insulating GaAs substrate by MOVPE, an aluminum-containing group III-V mixed crystal layer having a lattice constant, which is different by not less than 1% from the lattice constant of the semi-insulating GaAs substrate, said compound semiconductor epitaxial wafer further comprising a doped layer in which at least one dopant selected from the group consisting of selenium, tellurium, and sulfur has been doped as an n-type dopant by homogeneous doping or planar doping.

According to the second feature of the invention, there are provided various devices using the compound semiconductor epitaxial wafer according to the first feature of the invention. Specifically, the device of the invention may be a field-effect transistor comprising the compound semiconductor epitaxial wafer.

The device of the invention may be a bipolar transistor comprising the compound semiconductor epitaxial wafer.

The device of the invention may be a photodetector comprising the compound semiconductor epitaxial wafer.

The device of the invention may be a light emitting device comprising the compound semiconductor epitaxial wafer.

The device of the invention may be a composite device comprising a combination of at least two of the field-effect transistor, the bipolar transistor, the photodetector, and the light emitting device each comprising the compound semiconductor epitaxial wafer.

The device of the invention may be an integrated circuit device comprising a combination of at least two of the field-effect transistor, the bipolar transistor, the photodetector, and the light emitting device each comprising the compound semiconductor epitaxial wafer.

### BRIEF DESCRIPTION OF THE DRAWINGS

The invention will be explained in more detail in conjunction with the appended drawings, wherein:

FIG. 1 is a diagram showing the construction of a conventional compound semiconductor epitaxial wafer;

FIG. 2 is a diagram showing the construction of a preferred embodiment of the compound semiconductor epitaxial wafer according to the invention;

FIG. 3 is a diagram showing the construction of a preferred embodiment of the compound semiconductor epitaxial wafer according to the invention;

FIG. 4 is a diagram showing the construction of a comparative compound semiconductor epitaxial wafer; and

FIG. 5 is a diagram showing the relationship between molar concentration and carrier density for the epitaxial wafer shown in FIG. 3 and the epitaxial wafer shown in FIG. 4.

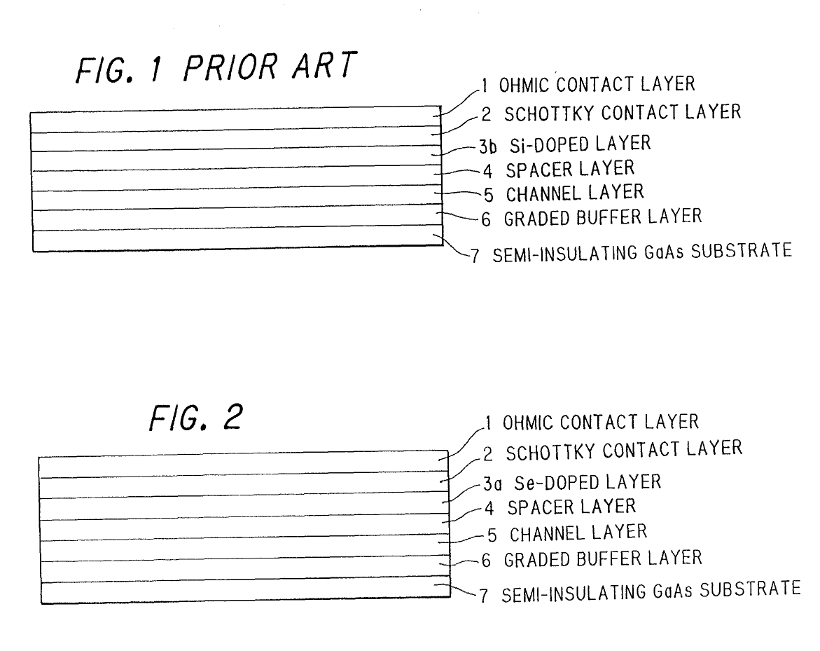

### DESCRIPTION OF THE PREFERRED EMBODIMENTS

Preferred embodiments of the invention will be explained in detail in conjunction with the accompanying drawings.

FIG. 2 is a diagram showing the construction of a preferred embodiment of the compound semiconductor epitaxial wafer according to the invention.

This epitaxial wafer comprises a semi-insulating GaAs substrate 7 and, provided on the semi-insulating GaAs substrate 7 in the following order, a graded buffer layer 6, a channel layer 5, a spacer layer 4, a selenium-doped layer 3a, a Schottky contact layer 2, and an ohmic contact layer 1.

This epitaxial wafer has an InAlAs/InGaAs-base HEMT laminate structure, and uses selenium as a dopant for the InAlAs/InGaAs-base system grown by MOVPE. Tellurium or sulfur may be used instead of selenium. Alternatively, two or all of selenium, tellurium, and sulfur may be used.

That is, this compound semiconductor epitaxial wafer comprises a semi-insulating GaAs substrate 7 and, grown on the semi-insulating GaAs substrate 7 by MOVPE, an aluminum-containing group III-V mixed crystal layer having a lattice constant, which is different by not less than 1% from the lattice constant of the semi-insulating GaAs substrate 7, wherein the compound semiconductor epitaxial wafer further comprises a doped layer in which at least one dopant selected from the group consisting of selenium, tellurium, and sulfur has been doped as an n-type dopant by homogeneous doping or planar doping.

The use of this dopant can provide an epitaxial wafer with high carrier density. Thus, the parasitic resistance can be lowered, and HEMT having high gm (mutual conductance) can be prepared. Further, the lowered resistance can significantly increase the freedom of device design.

Preferred embodiments of the invention will be explained in more detail. However, it should be noted that the invention is not limited to these preferred examples only.

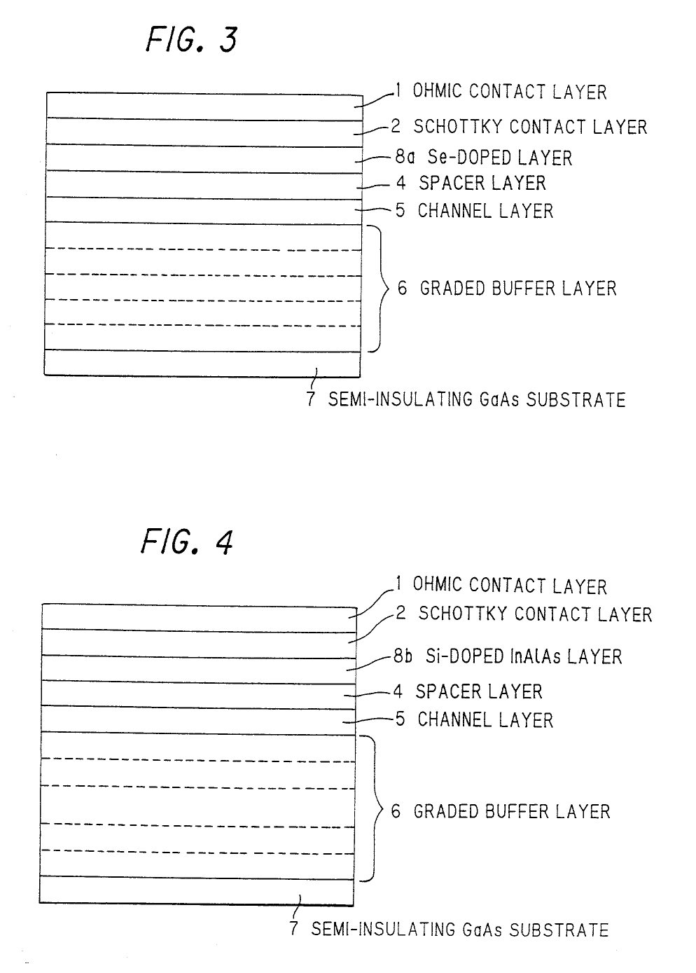

FIG. 3 is a diagram showing the construction of one preferred embodiment of the compound semiconductor epitaxial wafer according to the invention.

In this epitaxial wafer, a graded buffer layer 6 of un-InAlAs is grown on a semi-insulating GaAs substrate 7 by MOVPE in such a manner that the content of indium is gradually increased to 0.15, 0.23, 0.30, 0.35, and 0.40 from the semi-insulating GaAs substrate 7 side and the thickness of each layer is 100 nm, that is, the total layer thickness is 500 nm. A channel layer 5, a spacer layer 4, and a selenium-doped layer 8a grown by 200 nm as a homogeneously doped layer of InAlAs with an indium content of 0.40 are provided on the graded buffer layer 6. A Schottky contact layer 2 and an ohmic contact layer 1 of silicon-doped n-InGaAs (20 nm) with an indium content of 0.41 are provided on the selenium-doped layer 8a.

In the growth of the epitaxial wafer, trimethylindium (TMI), trimethylaluminum (TMA), and trimethylgallium (TMG) are respectively used for indium, aluminum, and gallium as the group III elements, arsine gas (AsH₃) is used for the group v element, and hydrogen selenide (H₂Se) gas is used for the dopant.

FIG. 4 is a diagram showing the construction of a comparative compound semiconductor epitaxial wafer.

The epitaxial wafer shown in FIG. 4 is different from the epitaxial wafer shown in FIG. 3 in that a silicon-doped InAlAs layer is provided instead of the selenium-doped layer.

In this epitaxial wafer, a graded buffer layer 6, a channel layer 5, a spacer layer 4, a silicon-doped InAlAs layer 8b, a Schottky contact layer 2, and an ohmic contact layer 1 are provided in that order on a semi-insulating GaAs substrate 7.

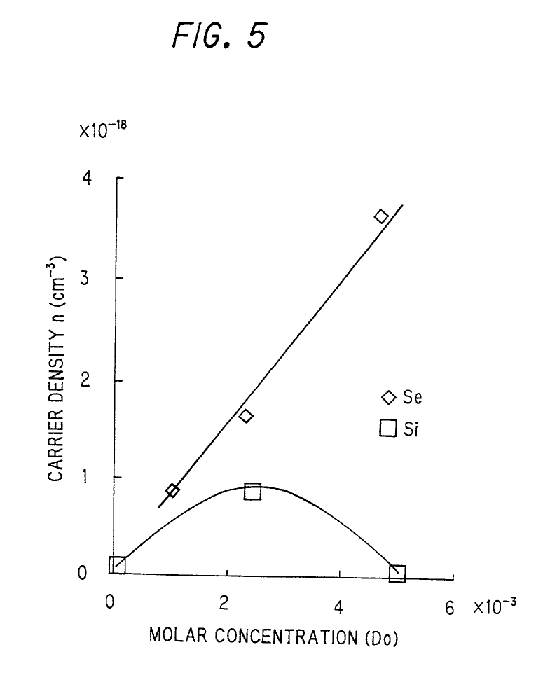

FIG. 5 is a diagram showing the relationship between molar concentration and carrier density for the epitaxial wafer shown in FIG. 3 and the epitaxial wafer shown in FIG. 4. The abscissa represents molar concentration and the ordinate represents carrier density.

As is apparent from FIG. 5, selenium doping can realize higher molar concentration doping than silicon doping.

Here in the above preferred embodiment, an InAlAs layer with an indium content of 0.40 has been formed on a GaAs substrate. When the difference in lattice constant between the substrate and the aluminum-containing epitaxial layer to be doped is not less than 1%, however, the contemplated effect can be attained even in the case of the formation of a combination of all the group III-V elements.

In the above preferred embodiment, selenium has been used as the n-type dopant. The invention, however, is not limited to this only, and tellurium or sulfur may be used instead of selenium.

In the above preferred embodiment, the invention has been applied to the epitaxial growth of HEMT structure. The invention, however, is not limited to this preferred embodiment only, and is effectively applied to other devices, that is, all of bipolar transistors including hetero-type bipolar transistors, APDs (avalanche photodiodes), PIN diodes and other photodetectors, LEDs, LDs and other light emitting devices, and composite devices comprising a combination of these devices, integrated ICs and the like.

As is apparent from the foregoing description, according to the invention, when at least one member selected from the group consisting of selenium, tellurium, and sulfur is used as an n-type dopant, compound semiconductor epitaxial wafers with high carrier density can be realized. The use of this epitaxial wafer can lower parasitic resistance and can provide HEMT having high gm. Further, the lowered resistance can significantly increase the freedom of device design.

In summary, according to the invention, compound semiconductor epitaxial wafers with high carrier density and devices using the same can be advantageously realized.

The invention has been described in detail with particular reference to preferred embodiments, but it will be understood that variations and modifications can be effected within the scope of the invention as set forth in the appended claims.

What is claimed is:

1. A compound semiconductor epitaxial wafer comprising a semi-insulating GaAs substrate and, grown on the semi-insulating GaAs substrate by MOVPE, an aluminum-containing group III-V mixed crystal layer having a lattice constant, which is different by not less than 1% from the lattice constant of the semi-insulating GaAs substrate, said compound semiconductor epitaxial wafer further comprising a doped layer in which at least one dopant selected from the group consisting of selenium, tellurium, and sulfur has been doped as an n-type dopant by homogeneous doping or planar doping.

2. A field-effect transistor comprising the compound semiconductor epitaxial wafer according to claim 1.

3. A bipolar transistor comprising the compound semiconductor epitaxial wafer according to claim 1.

4. A photodetector comprising the compound semiconductor epitaxial wafer according to claim 1.

5. A light emitting device comprising the compound semiconductor epitaxial wafer according to claim 1.

6. A composite device comprising a combination of at least two of the field-effect transistor, the bipolar transistor, the photodetector, and the light emitting device each comprising the compound semiconductor epitaxial wafer according to claim 1.

7. An integrated circuit device comprising a combination of at least two of the field-effect transistor, the bipolar transistor, the photodetector, and the light emitting device each comprising the compound semiconductor epitaxial wafer according to claim 1.
